(19) United States
(12) Patent Application Publication
(10) Pub. No.: US 2013/0130428 A1
(43) Pub. Date: May 23, 2013

(54) METHOD OF MAKING A SPATIALLY SENSITIVE APPARATUS

(71) Applicants: Robert D. TeKOLSTE, Charlotte, NC (US); Alan D. KATHMAN, Charlotte, NC (US)

(72) Inventors: Robert D. TeKOLSTE, Charlotte, NC (US); Alan D. KATHMAN, Charlotte, NC (US)

(21) Appl. No.: 13/737,284

(22) Filed: Jan. 9, 2013

Related U.S. Application Data
(62) Division of application No. 12/292,312, filed on Nov. 17, 2008.
Application No. 12/292,312 is a continuation-in-part of application No. 11/723,279, filed on Mar. 19, 2007, now Pat. No. 7,453,575.
Application No. 11/723,279 is a continuation of application No. 10/879,519, filed on Jun. 30, 2004, now Pat. No. 7,202,955.

(51) Int. Cl. H01L 27/146

(52) U.S. Cl. CPC H01L 27/14685
USPC 438/70

(57) ABSTRACT

A spectrometer for use with a desired wavelength range includes an array of filters. Each filter outputs at least two non-contiguous wavelength peaks within the desired wavelength range. The array of filters is spectrally diverse over the desired wavelength range, and each filter in the array of filters outputs a spectrum of a first resolution. An array of detectors has a detector for receiving an output of a corresponding filter. A processor receives signals from each detector, and outputs a reconstructed spectrum having a second resolution, the second resolution being higher than any of the first resolution of each filter. Filters and detectors may be arranged into a plurality of imaging units, each imaging unit including first and second filters and first and second photosensing regions. A processor receives signals from each imaging unit, and generates a reconstructed spatial image comprised of discrete spatial units corresponding to each imaging unit.

### CROSS REFERENCE TO RELATED APPLICATIONS

This is a divisional application based on pending application Ser. No. 12/292,312, filed Nov. 17, 2008, which in turn is a continuation-in-part application based on application Ser. No. 11/723,279, filed Mar. 19, 2007, and issued as U.S. Pat. No. 7,453,575 B2, which is a continuation application based on application Ser. No. 10/879,519, filed Jun. 30, 2004, and issued as U.S. Pat. No. 7,202,955 B2, the entire contents of all of which are hereby incorporated by reference.

### BACKGROUND OF THE INVENTION

1. Field of the Invention

The present invention is directed to a spectrally diverse and spatially sensitive apparatus, sometimes referred to as a spectral imager, and associated methods. More particularly, the present invention is directed to an apparatus having spectral and spatial sensitivity by including multiple arrays of wavelength differentiating elements which are not designed for a specific wavelength.

2. Description of Related Art

Conventional spectrometers typically use gratings or thin film filters to discriminate between wavelengths. Gratings are expensive and generally throw away a lot of light due to the modal filtering performed by the gratings. Thin film filters need to be provided in an array for each spectrometer and require multiple coating passes, also increasing cost.

Further, both of these solutions are designed to provide a particular band pass, e.g., a notch filter which only allows a very narrow wavelength range through. An example of such a filter spectrum is shown in FIG. 1. This is not a very efficient use of the light in these systems.

Much of the development in spectrometers has been directed to providing higher resolution systems, which, while increasing accuracy, serves to exacerbate the waste of light. Further, these systems tend to be very sensitive to incident angle. Finally, as wavelength resolution increases, the sensitivity to noise also increases. For many uses, this is acceptable. However, there are many situations using a spectrometer that cannot afford throwing away light and need to be angularly robust.

While spectrometers offer advantages for identifying spectral content of certain wave fronts, they may be unable to discriminate spatial information. Additional benefits may be recognized with a sensing apparatus that is able to provide spatial imaging content while maintaining increased efficiency and angular robustness in sensing spectral information.

### SUMMARY OF THE INVENTION

The present invention is therefore directed to a spectrometer and associated methods that substantially overcome one or more of the problems due to the limitations and disadvantages of the related art.

It is a feature of the present invention to provide a spectrometer that exploits much of the input light. It is another feature of the present invention to provide a spectrometer that includes a plurality of individual filters, each of which do not have a narrow band pass. It is yet another feature of the present invention to provide a spectrometer which is relatively insensitive to angle.

At least one of the above and other features and advantages may be realized by providing a spectrometer for use with a desired wavelength range including an array of filters, each filter outputting at least two non-contiguous wavelength peaks within the desired wavelength range, the array of filters being spectrally diverse over the desired wavelength range, wherein each filter in the array of filters outputs a spectrum of a first resolution, an array of detectors, each detector receiving an output of a corresponding filter, and a processor receiving signals from each detector, the processor outputting a reconstructed spectrum having a second resolution, the second resolution being higher than any of the first resolution of each filter.

Each filter may include a substrate and a pattern on the substrate, the pattern being in a material having a higher refractive index than that of the substrate. The pattern may have features on the order of or smaller than a wavelength of the desired wavelength range. The pattern varies in at least one of depth and period across the array of filters. Input light may be transmitted through the substrate and the pattern or may be reflected from the pattern. A period of the pattern across the array of filters may be on the order of or smaller than a wavelength of the desired wavelength range.

Each filter may include an etalon. The etalons in the array of filters may have varying cavity lengths. The cavity length may be on an order of magnitude of a wavelength in the desired wavelength range. The etalon may be an air gap etalon or a solid etalon. The varying cavity length may be realized by providing steps of varying height for each etalon.

The processor may output a reconstructed spectrum of input light by applying the inverse filter function to the signals output by the detectors. The outputs of the array of filters may be substantially constant with respect to an angle of light incident thereon. The array of filters may be provided directly on the array of detectors. Any two filters in the array of filters may have transmittance vectors that are linearly independent of one another and are not orthogonal. Multiple filters of the array of filters may pass overlapping wavelength ranges. Each detector includes a plurality of sensing portions. The array of filters may be continuous.

At least one of the above and other features and advantages of the present invention may be realized by providing a method of making a spectrometer for use with a desired wavelength range, including forming an array of filters, each filter outputting at least two non-contiguous wavelength peaks within the desired wavelength range, the array of filters being spectrally diverse over the desired wavelength range, wherein each filter in the array of filters is varied across the array, and providing an array of detectors, each detector receiving an output of a corresponding filter.

Spatial information may be obtained using an apparatus that includes a plurality of imaging units, each imaging unit including first and second filters and first and second photosensing regions. In this device, the filters output at least two discrete wavelength peaks within a desired wavelength range and are spectrally diverse over the desired wavelength range. Further, each photosensing region receives an output of a corresponding filter. The device may include a processor that receives signals from each imaging unit and generates a reconstructed spatial image comprised of discrete spatial units corresponding to each imaging unit.

The imaging spectrometer may incorporate an array of filters that are grouped in arrays of imaging units. Each imaging unit includes at least first and second filters and each filter outputs at least two discrete wavelength peaks in addition to being spectrally diverse within a desired wavelength range. The plurality of imaging units are arranged in a nominally recurring spatial pattern and the size of the imaging units are sufficiently large that each imaging unit is spatially diverse over the array of recurring imaging units and within the desired wavelength range. The first and second filters may be sized to correspond to sensing regions of an imaging sensor.

A spatially sensitive spectrometer may be constructed by forming a plurality of imaging units by combining first and second filters and first and second photosensing regions. Each filter may be characterized as including at least two discrete wavelength peaks within the desired wavelength range, with the first and second filters being spectrally diverse over the desired wavelength range. Spatial information may be achieved by arranging each photosensing region to receive light output of a corresponding filter and further arranging the plurality of imaging units into a nominally recurring spatial pattern, with the first and second photosensing regions in each imaging unit being spatially diverse over the recurring spatial pattern.

### BRIEF DESCRIPTION OF THE DRAWINGS

The above and other features and advantages of the present invention will become readily apparent to those of skill in the art by describing in detail embodiments thereof with reference to the attached drawings, in which:

FIG. 1 is a plot of transmittance versus wavelength for a conventional notch filter;

FIG. 2 is a plot of transmittance versus wavelength for a filter in accordance with the present invention;

FIG. 3 is schematic side view of a filter in accordance with a first embodiment of the present invention;

FIG. 4 is a plot of the wavelength versus transmittance of a filter in accordance with an embodiment of the present invention with varying input angles;

FIG. 5 is an plot of wavelength versus transmittance for a spectrometer in accordance with an embodiment of the present invention;

FIG. 6 is a schematic top view of an array of filters according to the first embodiment of the present invention;

FIG. 7 is a schematic side view of a spectrometer according to a second embodiment of the present invention, along with representative exemplary outputs;

FIG. 8 is a schematic side view of a filter according to a third embodiment of the present invention;

FIG. 9 is a schematic side view of a filter according to a fourth embodiment of the present invention;

FIG. 10 is a plot of transmittance versus wavelength for a spectrometer having filters according to the second embodiment of the present invention, with twenty steps;

FIG. 11 is a plot of the original spectra input to the spectrometer and the reconstructed spectra from FIG. 10; and

FIG. 12 is a plot of the transmittance versus wavelength of a spectrometer of FIG. 10 with varying input angles.

FIG. 13 is schematic side view of a filter including multiple sensing regions per filter in accordance with one embodiment of the present invention;

FIG. 14 is schematic side view of a filter including a single sensing region per filter in accordance with one embodiment of the present invention;

FIG. 15 is schematic side view of a filter including repeated filter arrays over a detector array in accordance with one embodiment of the present invention; and

FIG. 16. is schematic top view of multiple repeated filter arrays in accordance with one embodiment of the present invention.

FIG. 17. graphically depicts a processing system to manage the data from such an inventions, resolving the image data into appropriate spatial relationships and spectral bands in accordance with one embodiment of the present invention.

### DETAILED DESCRIPTION OF THE INVENTION

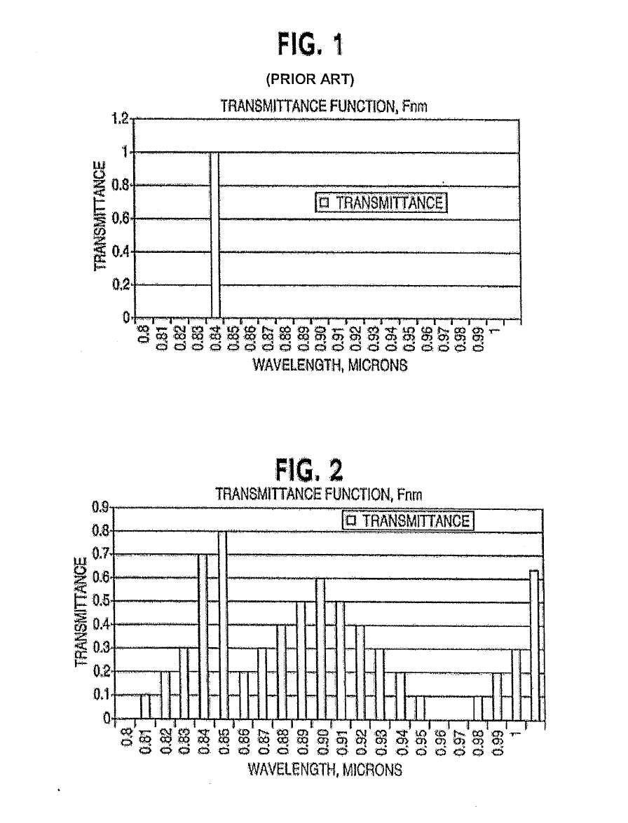

FIG. 1 is a plot of transmittance versus wavelength for a conventional notch filter. As can be seen therein, the conventional notch filter only allows a very narrow bandwidth of light through, to allow accurate determination of wavelength of light being measured. Numerous such filters may be provided to monitor a spectrum of interest.

In contrast to the conventional notch filter, a filter according to the present invention, as shown in FIG. 2, passes numerous wavelengths at various transmittance levels. By providing an array of these filters, a spectrally diverse transmittance spectrum can be realized. Thus, rather than providing an array of filters each responsive to a specific wavelength to cover a desired wavelength range, an array of filters that cumulatively provide the needed spectral diversity such that wavelengths of input light may be discerned with acceptable accuracy is used in accordance with the present invention. By determining the characteristics of each filter in the array and using available information provided from each filter, a high resolution spectrum may be extracted from a plurality of low resolution spectra.

The response of the spectrometer may be generally represented as:

Iₙ=∫Fₙ(λ)S(λ)dλ (1)

where I is the intensity of light output from the spectrometer, F is the individual filter response for each of n filters and S is the input spectrum. In discretized form:

$${I}_{n} = {\sum }_{m = 1}^{N} {F}_{n} ( {λ}_{m} ) S ( {λ}_{m} ) Δ λ = {F}_{n m} {S}_{m} \qquad ( 2 )$$

Thus, knowing the filter response and the output of the spectrometer, the input spectrum may be represented as:

Sₘ=Fₙₘ⁻¹Iₙ (3)

While the number of such filters required to achieve a sufficient level of resolution will be greater than the number of bandpass filters for comparable resolution, a spectrometer using such filters may have a higher light efficiency and may be more angularly robust.

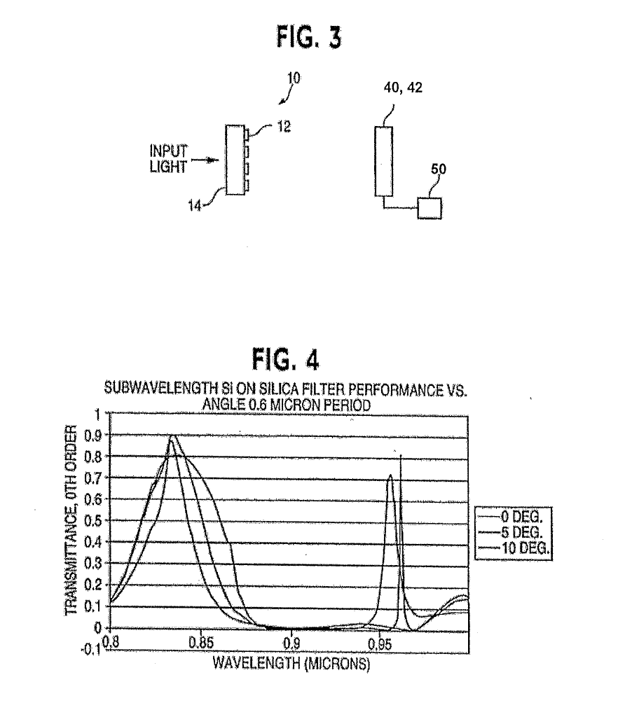

A first embodiment of the present invention realizes a spectrally diverse output by creating a highly dispersive structure 10, shown in FIG. 3. The structure 10 includes a patterned high index material 12, i.e., having a refractive index higher than that of the substrate, on a substrate 14. An array of these structures 10 are used in a first embodiment of a spectrometer of the present invention. Light transmitted by the array of structures 10 is detected by a detector array 40. The outputs of detectors 42 in the detector array 40 are provided to a processing system 50, which can then determine the input spectrum in accordance with Equation (3). Various conventional elements may be provided as required, such as lenses for directing the light onto the array of structures 10 and relaying the light between the array of structures 10 and the detector array 40. The structure 10 may also be used in a reflective mode, with the detector array 40 positioned accordingly. The array of structures 10 may be secured directly to the detector array 40.

The substrate 14 may be fused silica or Pyrex. The high index material may be silicon or titanium dioxide. The high index material should be patternable, have an index of refraction higher than that of the substrate and be at least sufficiently transmissive at the wavelengths of interest. The relative indices between the substrate and the material having the pattern aid in the creation of a spectrally diverse output. The pattern may have sub-wavelength or near wavelength features, i.e., on the order of the wavelength of light of interest or smaller. The pattern may result in the substrate being exposed, may leave some of the high index material on the substrate even where an indent is present or there may be another layer of material between the high index material and the substrate.

An example of such a structure to be used in the visible to near infrared range includes a fused silica substrate with patterned silicon having a period of 0.6 microns and a thickness or depth of 0.65 microns. A plot of transmittance of zero-order light versus wavelength for this example is shown in FIG. 4. This plot also illustrates that the performance of this structure is relatively insensitive to changes in incident angle, i.e., good discrimination performance is maintained as the angle changes.

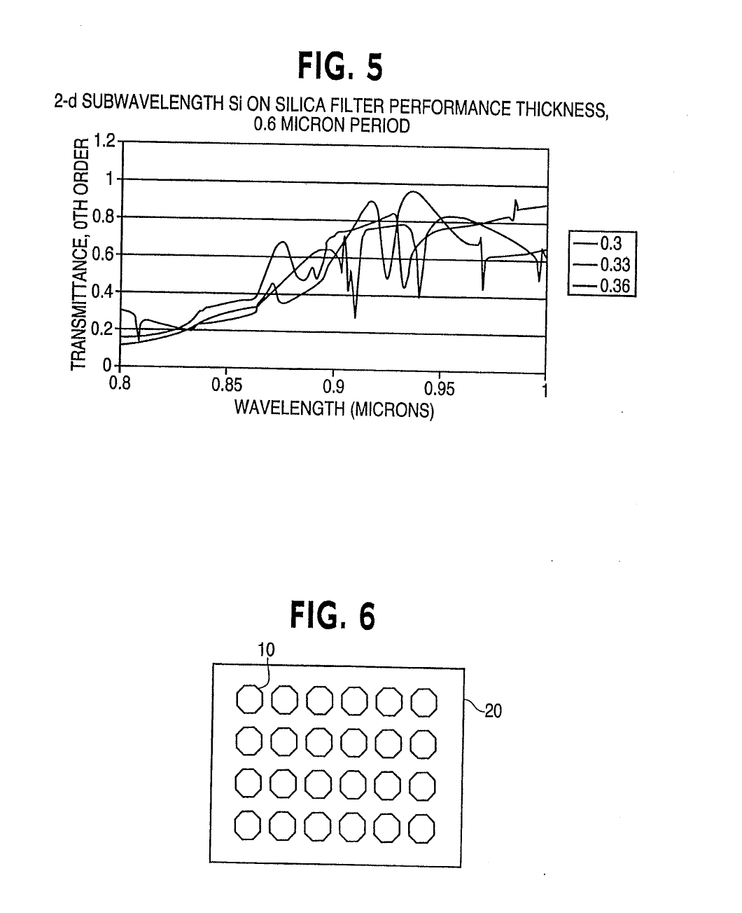

Another example of such a spectrometer for use in the visible to near infrared region has gratings in silicon on silica having the same period, here 0.6 microns, with varying sub-wavelength depths in the silicon, e.g., 0.3, 0.33 and 0.36 microns. A plot of transmittance of zero-order light versus wavelength for this example is shown in FIG. 5. As can be seen in FIG. 5, the spectra vary dramatically with a change in the etch depth. While there is no clear bandpass, as long as there is sufficient spectral diversity such that different wavelengths will have different transmittance over a desired bandwidth, this is sufficient.

A plurality of these structures 10 may be provided in an array 20 as shown in FIG. 6. Variations in the transmission spectra across the array 20 may be realized by varying the period and/or the thickness of the features of the pattern. By varying the pattern, different transmission spectra can be realized for high spectral diversity. The actual pattern used may be iteratively computed by altering one or both of the period and the depth until sufficient spectral diversity with adequate resolution is provided across a desired wavelength range. In an idealized structure, the resolution would be equal to the wavelength range or band of interest divided by the number of filters. However, in practice, there will be some overlap in the wavelength regions covered by the filters for redundancy and to increase the signal-to-noise ratio. The period may be between the wavelength in the high index material and the wavelength in the low index material.

To achieve a sufficiently spectrally diverse output, the period and/or depth of the pattern may be iteratively altered until the desired output is obtained. The filter may also be used in a reflective mode in which the input light is incident on the structure at an angle, e.g., 45°. This may result in improved contrast, since the difference in refractive index between the high index pattern and the ambient environment is typically greater than that between the high index pattern and the substrate.

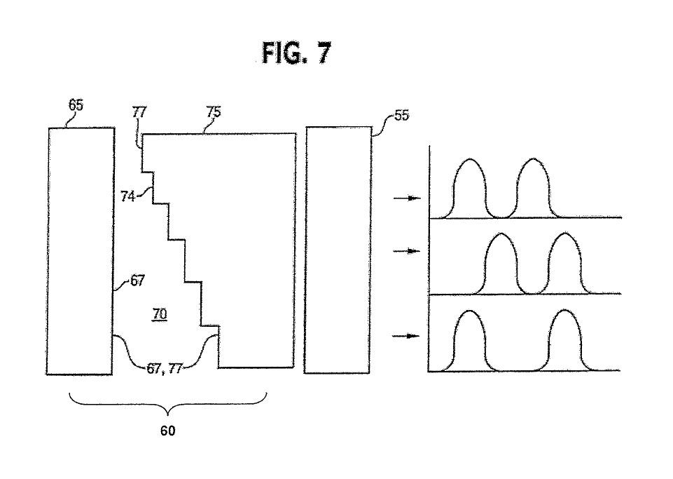

In another configuration of the present invention, spectrally diverse transmission may be realized using etalons 60 to create the filters, an example of which is shown in FIG. 7. Etalon signals behave similarly to Fourier spectra, so a more deterministic approach may be used in creating an array of etalons, rather than the iterative approach above. For example, the function F of each etalon may be given as:

$$F ( λ ) = {F}^{′} ( \frac{2 π x}{Δ λ} ) \qquad ( 4 )$$

where x=λ−λ₀, λ₀ is a middle wavelength in the range of interest, Δλ=λₘₐₓ−λₘᵢₙ, where λₘₐₓ is the maximum wavelength in the range and λₘᵢₙ is the minimum wavelength in the range, and F′ is defined between −π to π. If this is then approximated as a Fourier series assuming the output is a true sinusoid, then:

$${F}^{′} ( \frac{2 π x}{Δ λ} ) = \frac{{a}_{0}}{2} + {a}_{1} cos ( \frac{2 π x}{Δ λ} ) + {b}_{1} sin ( \frac{2 π x}{Δ λ} ) + … + {a}_{n} cos ( \frac{2 n π x}{Δ λ} ) + {b}_{n} sin ( \frac{2 n π x}{Δ λ} ) \qquad ( 5 )$$

The number n selected will determine the number of etalon/detector pairs needed, i.e., 2n, so that there is an etalon for each sine and cosine. Etalons having behavior that may not be so approximated with sufficient accuracy may still be used in accordance with the present invention, although the mathematical model required will be more complicated. While this model may be useful in beginning a design of the etalons, the more general approach outlined above in equations (1) to (3) is used to obtain the reconstructed spectra.

Each etalon has multiple resonance peaks, as can be seen with the three representative outputs as shown in FIG. 7. These peaks occur at different wavelengths due to the different cavity lengths of the different etalons. Since the etalons will operate over a range of incident angles, the reflectance on the opposing surfaces thereof will be selected to provide the best combination of signal reconstruction, robustness to noise and light throughput. Resolution of the spectrometer using etalons may be improved by increasing the finesse or the cavity length of the etalons. The range of cavity lengths to be used corresponds roughly with wavelength. If the cavity length is too large, the respective etalon peaks will be too close together, and will be more sensitive to incident angle. Further, for shorter cavity lengths, a larger cone angle can be accepted, increasing light efficiency. However, if the cavity lengths are too short, the resolving power is decreased and contrast is limited.

For operation in the visible region, these etalons may have cavity lengths of less than 10 microns. If the cavity lengths are too long, e.g., roughly greater than 100 microns, the etalon becomes highly angularly sensitive and the spectrometer constructed there from has a low light efficiency. If the cavity lengths are too short, e.g., roughly 1 micron or less, there is lower resolving power and limited contrast.

The etalons 60 forming the filters of a second embodiment are shown in FIG. 7 include two substrates 65 and 75 defining a cavity 70 therebetween. Each substrate has a reflective coating 67, 77, respectively, thereon. One of the substrates 75 has steps 74 therein for altering the depth of the cavity 70 across the array. The depth of the cavity 70 along with the reflective coatings 66, 77 defines each etalon 60.

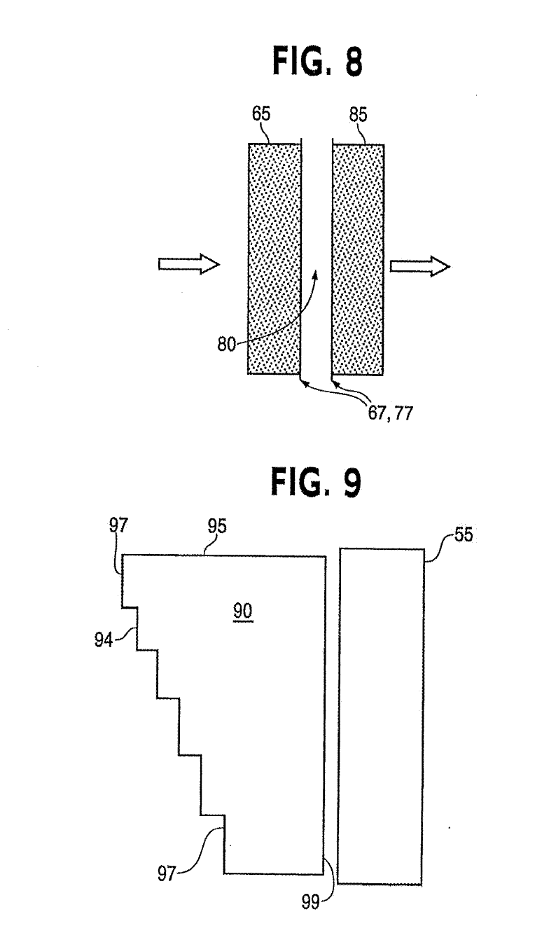

Alternatively, as shown in FIG. 8, the filters of a third embodiment have each etalon may include two planar substrates 65, 85, defining a cavity 80 therebetween. The cavity length is varied across the array to create different etalons 60.

A further alternative etalon forming the filters of a fourth embodiment is shown in FIG. 9. Here, a single stepped substrate 95 is used. There are reflective coatings 97, 99 on either side of the substrate 95 and the cavity 90 is internal to the substrate 95. The substrate 95 may be a high index material, but also needs to be transparent to the wavelengths of interest.

Again, a spectrometer using the etalon array includes a corresponding detector array 55 and a processor 50. The etalons are located between the input light and the detectors. The etalons may be at an intermediate image plane or right against the detector array.

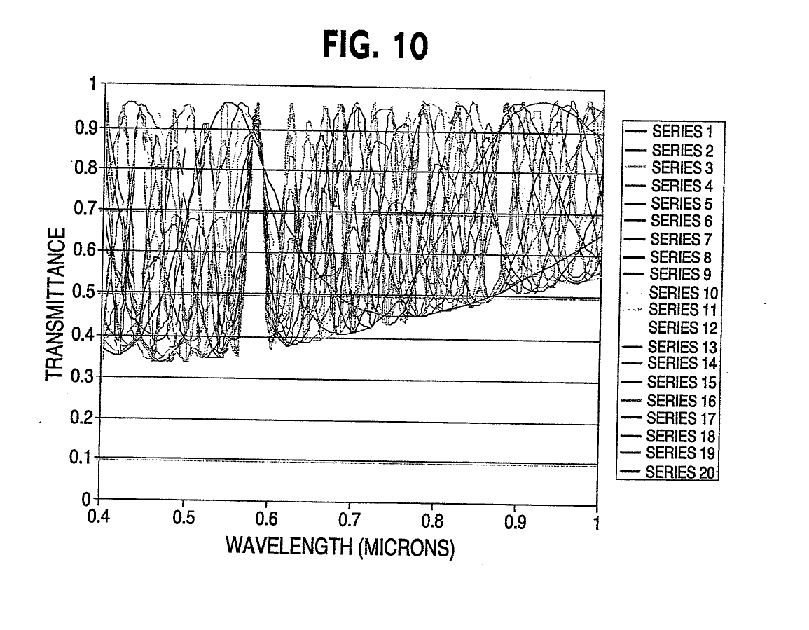

An example of spectra output from an array of twenty etalons 60 configured as the stepped air gap etalon of FIG. 7, having cavity depth between 0.2 and 4 microns and peak reflectances between 60-80%, is shown in FIG. 10. As can be seen therein, there is spectral diversity across the entire visible range, extending from the ultraviolet to the near infrared.

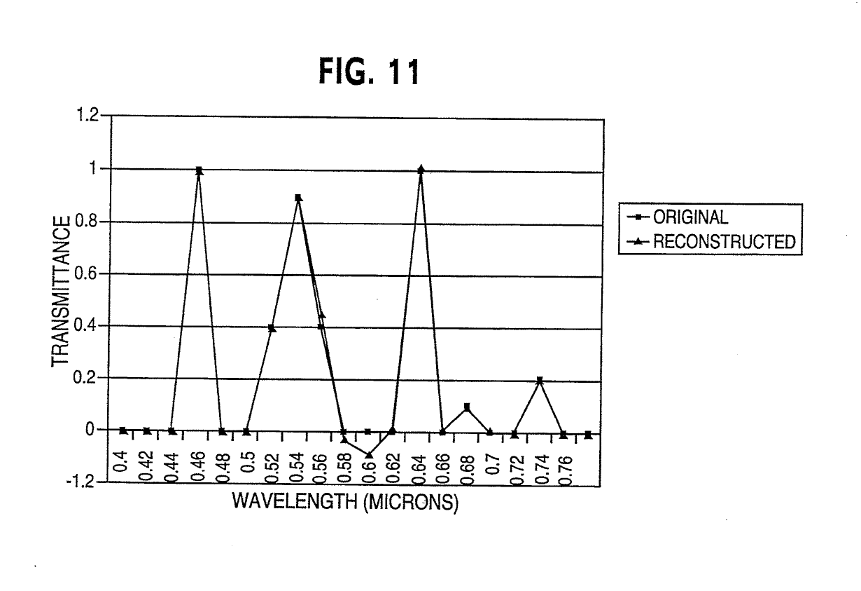

The input spectrum used to generate these spectra is shown in FIG. 11 as the square plot. The inverse filter function for each of these spectra was then applied to the spectra of FIG. 10 to generate the reconstructed spectra of FIG. 11, shown as the triangle plot. The lighter plot of the reconstructed spectra overlays the darker plot of the original spectra. As can be seen therein, the reconstructed spectrum is very accurate, although the region right around 0.6 microns was difficult to resolve accurately, as would be expected from the spectra in FIG. 10.

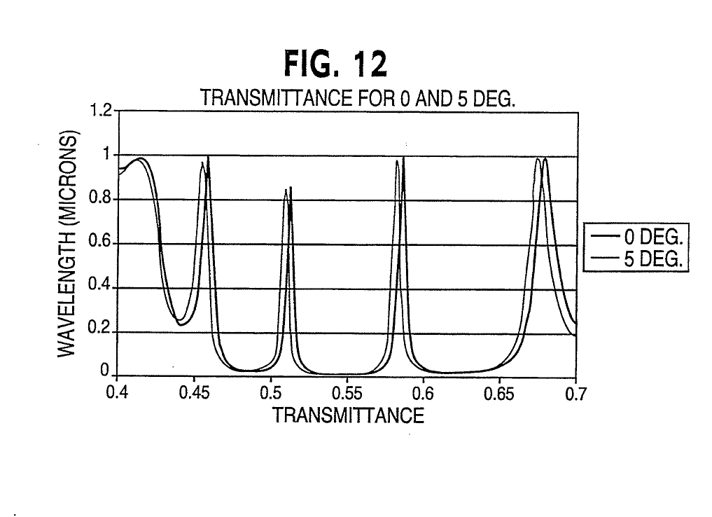

FIG. 12 is a plot of transmittance versus wavelength for different illumination angles of the spectrometer providing the spectra of FIGS. 10 and 11. As can be seen therein, alteration in illumination angle just shifts the spectra, without radically altering the nature thereof.

Since the filters of the spectrometer of the present invention are to be varied and are for providing spectral diversity rather than a specific response, the inherent variation arising from the manufacture of the filters may provide a more robust spectrometer. Particularly when these filters are made at the wafer level, variation across the wafer may actually help in increasing the spectral diversity. This allows the manufacturing tolerances to be eased.

While the above embodiments illustrate a detector element associated with a filter, the detector element may include more than one sensing region. Thus, light output from a single filter may be incident on more than one sensing region, and then an average signal from all these sensing regions may be output to the processor. This helps to reduce noise in the system.

Additionally, while the filters discussed above were assumed to be discrete filters in an array of filters, these filters may be continuous and the array becomes an arbitrary one of convenience of illustration. For example, instead of the stepped etalon of FIG. 7, a wedged etalon may be used.

Thus, by characterizing the filter function for each filter in an array of filters and then providing the inverse of these filter functions to the output of a corresponding detector array, an input spectrum may be reconstructed. According to the present invention, a spectrally diverse function may be created across an array of filters, either iteratively or deterministically. While no individual filter can discriminate a particular wavelength, the cumulative effect across the filters allows input light to be characterized across a desired wavelength range with a needed resolution. Properly designed, taking into account remaining filters of the array, the increase in the number of filters will increase the resolution. The transmittance vector of any two filters may be linearly independent and not orthogonal.

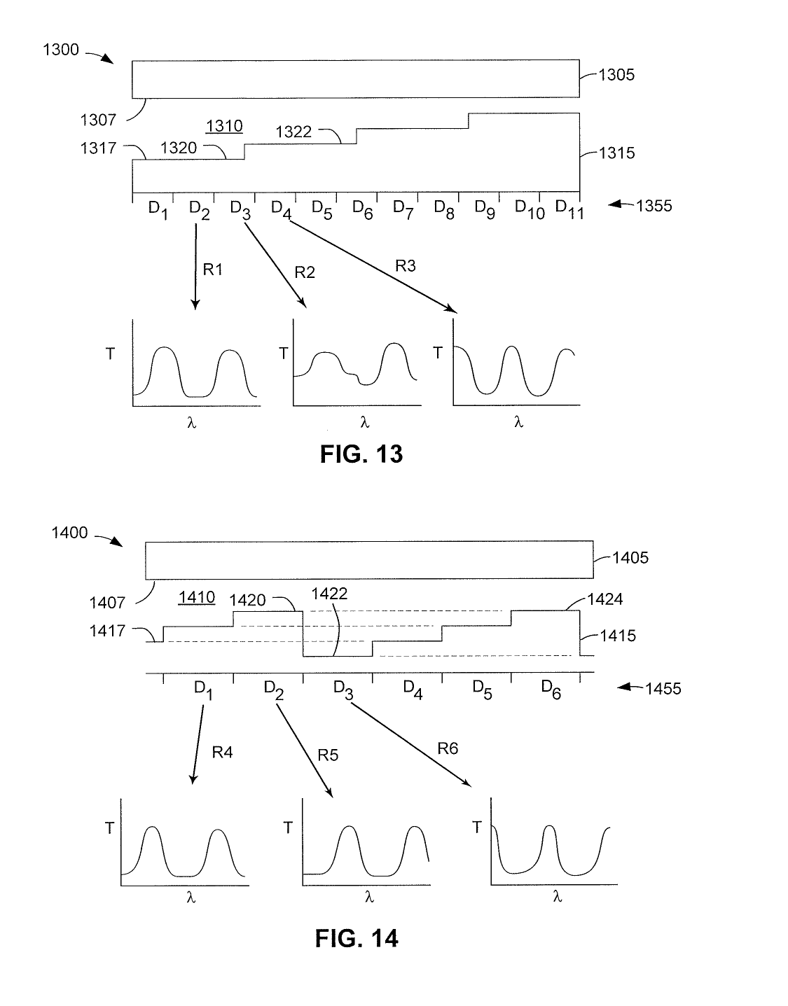

As suggested above, filters may be associated with detectors having a single sensing region or more than one sensing region. These different combinations are depicted graphically in FIGS. 13 and 14. In FIG. 13, an etalon filter 1300 includes two substrates 1305, 1315, each with respective reflective surfaces 1307, 1317 on opposing sides of an internal cavity 1310. In the embodiment shown, substrate 1315 includes a plurality of steps 1320, 1322 of varying height that change the length of the cavity 1310. The etalon filter 1300 is associated with a detector array 1355, that includes a plurality of discrete sensing portions (e.g., pixels in a CCD or CMOS sensor array) D1-D11.

The filter response at step 1320 detected by sensing region D2 is depicted by the spectral output identified by the arrow labeled R1. The spectral output is represented as a multi-modal response curve of transmittance T over a range of wavelengths □ (lambda). This same or similar spectral output will also be sensed by sensing region D1 since the cavity 1310 length at step 1320 is the same for sensing region D1 as it is for D2. This particular embodiment is one example of a filter that is associated with multiple detectors. In this case, an average signal from these sensing regions D1, D2 may be output to the processor.

Different sensing regions D3-D11 will generate different spectral outputs because each is associated with different cavity 1310 lengths. For example, the filter response at step 1322 detected by sensing region D4 is depicted by the spectral output identified by the arrow labeled R3. Spectral output R3 is different than spectral output R1 because of the difference in cavity 1310 length between steps 1320 and 1322. In some cases, a sensing region (e.g., D3 in the embodiment shown) may be positioned (intentionally or unintentionally) to receive electromagnetic energy from multiple filters. In this scenario, the sensing region D3 may detect, at least partially or in some combination, the filter response (identified by response R2) associated with each of the varying height steps 1320, 1322. Ultimately, as long as the array of filters 1310 and array of detectors 1355 cumulatively provide the needed spectral diversity, then the wavelengths of input light may be discerned with acceptable accuracy.

FIG. 14 shows one embodiment of an etalon filter array 1400, where each filter is associated with a single sensing region D1-D6 of detector 1455. In FIG. 14, an etalon filter 1400 includes two substrates 1405, 1415, each with respective reflective surfaces 1407, 1417 on opposing sides of an internal cavity 1410. In the embodiment shown, substrate 1415 includes a plurality of steps 1420, 1422 of varying height that change the length of the cavity 1410. The etalon filter 1400 is associated with a detector array 1455 that includes a plurality of discrete sensing regions D1-D6. In contrast with FIG. 13, each of the sensing regions D1-D6 in FIG. 14 is configured to detect the spectral response from a different stepped portion 1420, 1422 in the etalon array 1400. That is, the size of each sensing region D1-D6 and each step 1420, 1422 correlate so that each sensing region D1-D6 receives light that is emitted by filter array 1400 at a single step 1420, 1422. Depending on a particular part configuration, this may require that the step size 1420, 1422 be smaller, the same, or larger in area than the sensing region D1-D6. In some cases, light blocking features may be used to eliminate or reduce cross talk among sensing regions D1-D6.

In FIG. 14, the filter response at step 1410 detected by sensing region D1 is depicted by the spectral output identified by the arrow labeled R4. Similarly, sensing regions D2 and D3 detect different filter responses, R5 and R6, created by different step heights. In one embodiment, each step size 1420, 1422 is unique over an entire filter array, which means each sensing region D1-D6 has the capacity to generate a unique spectral response. In other embodiments such as the one shown in FIG. 14, the etalon filter 1400 includes a repeating structure such that non-adjacent, spatially diverse, sensing regions D1-D6 may detect a substantially similar spectral response. For example, steps 1420 and 1424 have similar heights so spaced apart sensing regions D2 and D6 may detect a substantially similar response R5. As described previously, an average signal from these sensing regions D2, D6 may be output to the processor to obtain an improved signal to noise ratio.

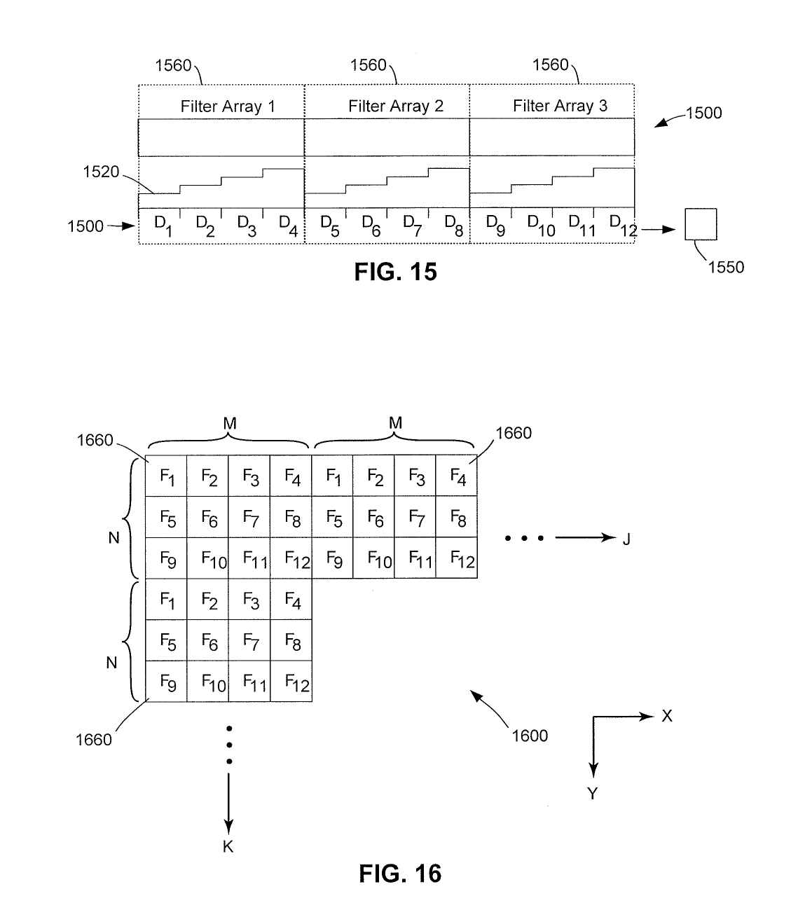

In another implementation, a certain amount of spatial information may be discerned from a repeating filter structure 1400. Generally, a spectrometer is unable to provide spatial information. By incorporating a repeating filter structure 1400, a certain amount of spatial information may be acquired. FIG. 15 illustrates an embodiment of a spectral imager created using etalon filters that is capable of providing spatial and spectral information. Specifically, FIG. 15 illustrates a side cross section view of an etalon filter array 1500 and a corresponding detector array 1555. In this particular embodiment, the etalon filters in Filter Arrays 1, 2, and 3 are configured similar to the embodiment in FIG. 14. That is, each step 1520 is associated with one sensing regions D1-D12 in the detector array 1555. In other embodiments, the individual filter steps may be associated with multiple sensing regions as in FIG. 13.

In one embodiment, Filter Arrays 1, 2, and 3 in FIG. 15 correlate to one another (i.e., are substantially similar to one another). With this configuration, sensing regions D1-D4 and D5-D8 and D9-D12 each detect a similar spectral response. However, a corresponding processing system 1550 is able to build a spatial map of the intensity differences sensed by those sensing regions D1-D4 and D5-D8 and D9-D12. In this manner, each Filter Array 1, 2, and 3 and its corresponding detector array D1-D4 and D5-D8 and D9-D12 form a spatial unit 1560. The spatial units 1560 are accumulated to build an entire image. Each spatial unit 1560 also forms a spectrometer as heretofore described. Consequently, the output of the processing system 1550 may include a spatial map of spectral content detected at each spatial unit 1560.

This spatial information can be extended to a 2-dimensional map as shown in FIG. 16. In the illustrated embodiment, a filter spatial unit 1660 having N by M discrete filters is repeated J times in the X direction and K times in the Y direction to produce an M×J×N×K filter array 1600. The filter array 1600 includes J×K spatial units 1660, each generating a potentially unique output response depending on the nature of the incoming light. In the illustrated embodiment, each spatial unit 1660 includes twelve (F1-F12) filters. The number of filters in each spatial unit 1660 may be increased as necessary to achieve a desired spectral resolution. For example, hundreds or thousands or more filters may make up each spatial unit 1660. In one embodiment, the discrete filters are steps in an etalon structure. Other embodiments may include other structures described herein.

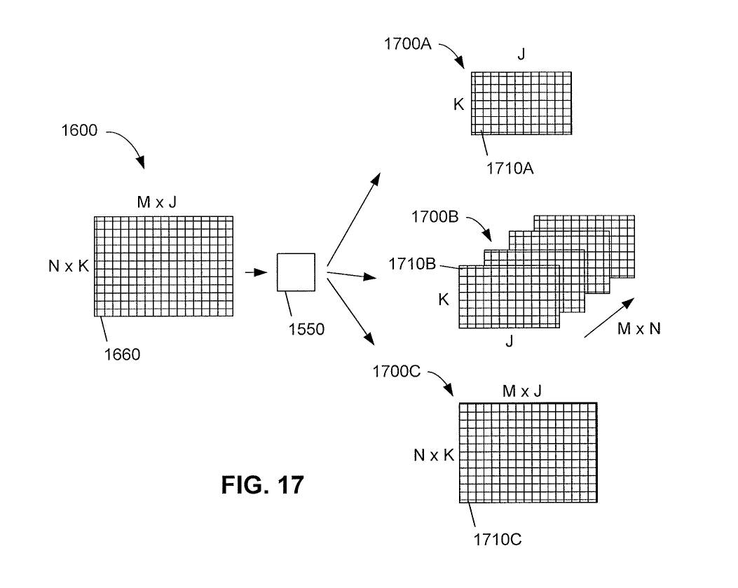

As shown in FIG. 17, a corresponding processing system 1550 is able to process the multiple N by M arrays of spectral data in different manners. In one embodiment, each of the J×K spatial units 1660 may be mapped to form a J×K image 1700 that includes discrete spatial units 1710A corresponding to the J×K spatial units 1660 in the filter/sensor array 1600. In another embodiment, individual N×M filters within the J×K spatial units 1660 may be mapped to form a J×K image 1700 that includes discrete spectral units 1710A corresponding to the N×M filters in the filter/sensor array 1600. In one implementation, the processing system 1550 simply maps the N×M spectral data to form one or more M×J×N×K multispectral or hyperspectral images 1700B. For example, a common use of multispectral imagery is to capture multiple images, each within a relatively narrow or defined spectral band. By contrast, hyperspectral imagery may involve the collection of a set of images over broader or even overlapping spectral bands. Images of contiguous spectral bands may be combined to form a three dimensional hyperspectral cube for processing and analysis. In this case, the J×K images also include discrete spatial units 1710B corresponding to the N×M filters in the filter/sensor array 1600. In another implementation, the processing system 1550 interpolates the spectral data to generate something more akin to a color image 1700C, where each individual spatial unit 1710C is defined by a spectral value corresponding to the to the N×M filters in the various J×K spatial units 1660 of the filter/sensor array 1600.

With the arrangement shown in FIG. 16, and for a given number of sensing regions, a tradeoff is achieved between spectral and spatial resolution. Greater spectral resolution may be achieved by increasing the size M×N of each spatial unit 1660. This in turn will reduce the total number J×K of spatial units 1660 in the filter array 1600. Conversely, greater spatial resolution may be achieved by decreasing the size M×N of each spatial unit 1660 to give a greater overall number J×K of spatial units 1660. Accordingly, the applicability of a spatially sensitive spectrometer can vary depending on the relative distribution of spatial/spectral units. Towards one extreme, the spatially sensitive spectrometer may be configured to acquire less spatial data and operate as a spectrometer, colorimeter, or imaging colorimeter. Towards the other extreme, the spatially sensitive spectrometer may be configured to acquire less spectral data and operate as a, color camera, or spectral imager as described above.

While the present invention is described herein with reference to illustrative embodiments for particular applications, it should be understood that the present invention is not limited thereto. Those having ordinary skill in the art and access to the teachings provided herein will recognize additional modifications, applications, and embodiments within the scope thereof and additional fields in which the invention would be of significant utility without undue experimentation.

1.-13. (canceled)

14. A method of making a spatially sensitive spectrometer for use with a desired wavelength range, comprising:
forming a plurality of imaging units by combining first and second filters and first and second photosensing regions, each filter characterized as including at least two discrete wavelength peaks within the desired wavelength range, the first and second filters being spectrally diverse over the desired wavelength range, and arranging each photosensing region to receive light output of a corresponding filter; and
arranging the plurality of imaging units into a nominally recurring spatial pattern, with the first and second photosensing regions in each imaging unit being spatially diverse over the recurring spatial pattern.

15. The method of claim 14, wherein the step of forming a plurality of imaging units comprises creating etalon filters of varying cavity lengths.

16. The method of claim 14, wherein the step of forming a plurality of imaging units comprises creating etalon filters with differing cavity materials.

17. The method of claim 14, further comprising sizing the filters to substantially match the size of individual pixels of an imaging sensor.

18. The method of claim 14, further comprising sizing the filters to overlap a plurality of individual pixels of an imaging sensor.

19. The method of claim 14, wherein the step of arranging the plurality of imaging units into a nominally recurring spatial pattern comprises forming a substantially repeating two-dimensional pattern of filters and photosensing regions.

20. The method of claim 14, further comprising coupling the photosensing regions to a processor configured to receive signals from each imaging unit, the processor further configured for reconstructing a spatial image comprised of discrete spatial units corresponding to each imaging unit.
